(19) United States
(12) Patent Application Publication
(10) Pub. No.: US 2023/0413502 A1
(43) Pub. Date: Dec. 21, 2023

(54) COMPONENT MOUNTER AND CLAMP CONTROL METHOD

(71) Applicant: FUJI CORPORATION, Chiryu (JP)

(72) Inventor: Shigeto ICHIKAWA, Nagoya-shi (JP)

(73) Assignee: FUJI CORPORATION, Chiryu (JP)

(21) Appl. No.: 18/252,101

(22) PCT Filed: Dec. 14, 2020
(86) PCT No.: PCT/JP2020/046506

§ 371 Date: May 8, 2023

(51) Int. Cl. H05K 13/04; H05K 13/00

(52) U.S. Cl. CPC H05K 13/0408; H05K 13/0015

(57) ABSTRACT

A component mounter includes a clamp device that includes a board presser plate, a clamper, and a lifting and lowering device configured to move up and down the damper by driving of a motor, the clamp device being configured to sandwich and clamp the board from both sides by moving the damper with the lifting and lowering device and bringing a board conveyed by a conveyance device into contact with the board presser plate. Then, in a clamp control routine, the component mounter sets a target position of the damper according to a thickness of a board such that a contacting surface of the damper moves to a contacted surface of a fixed side clamp member, and drives and controls the motor by position control such that a clamper position coincides with the target position.

### TECHNICAL FIELD

The present specification discloses a component mounter and a clamp control method.

### BACKGROUND ART

Conventionally, a component mounter that includes a board presser plate, a clamper, a lifting and lowering device for lifting and lowering the damper, includes a clamp device for holding the board by sandwiching the board between the damper and the board presser plate, and mounts an electronic component on the board clamped by the clamp device is known. For example, Patent Literature 1 discloses a component mounter that includes a clamp device for lifting a clamper at a high speed to a predetermined distance ahead of a target clamping position determined based on size data (thickness) of a board measured for each lot, switching from the high speed to a low speed, and lifting the damper in a case where the damper reaches the predetermined distance ahead of the target clamping position. In addition, Patent Literature 2 discloses a component mounter that includes a board surface height acquiring section for acquiring a position of a board clamped by a clamp device in an up-down direction, and applying a board surface height acquired by the board surface height acquiring section to mounting of an electronic component. Further, Patent Literature 3 discloses a board conveyance device for measuring a thickness of a board sandwiched by a pair of sandwiching pieces.

### PATENT LITERATURE

Patent Literature 1: JP-A-2017-103334
Patent Literature 2: JP-A-2003-289199
Patent Literature 3: JP-A-2015-060988

### SUMMARY OF THE INVENTION

### Technical Problem

However, in a case where an actual thickness of a board is larger than size data (thickness) because of an individual difference between boards, the board may be pressed against a board presser plate before reaching a target clamping position, that is, while lifting a clamper at a high speed, so that an excessive load may be generated in a motor or the board presser plate may be deformed. If the damper is lifted at a low speed from beginning, such a problem does not occur, but a long time is required for the clamping.

It is a main object of the present disclosure to clamp a board with an appropriate load while reducing time required for clamping.

### Solution to Problem

The present disclosure employs a following means in order to achieve the above-mentioned main object.

A component mounter of the present disclosure is a component mounter for mounting a component on a board, the gist of which is to include
a conveyance device configured to convey the board,
a clamp device including a fixed side clamp member, a movable side clamp member, and a moving device configured to move up and down the movable side clamp member by driving of a motor, the clamp device being configured to sandwich and clamp the board from both sides by moving the movable side clamp member with the moving device and bringing the board conveyed by the conveyance device into contact with the fixed side clamp member,
a sensor configured to measure a thickness of the board conveyed by the conveyance device, and
a control device configured to set a target position of the movable side clamp member configured to move a contacting surface of the board to a contacted surface of the fixed side clamp member based on a detected value of the sensor, the control device being configured to drive and control the motor by position control such that a position of the movable side clamp member coincides with the target position.

In the component mounter of the present disclosure, since it is possible to adjust the contacting surface of the board to the contacted surface of the fixed side clamp member regardless of the individual difference of the board, the board is less likely to be pressed against the fixed side clamp member with an excessive load. Therefore, it is possible to prevent the fixed side clamp member from being deformed or to avoid bending or breakage of the board. In addition, since the clamping is performed by the position control, it is possible to shorten the time required for the clamping.

### BRIEF DESCRIPTION OF DRAWINGS

FIG. 1 is a schematic configuration diagram of component mounter 10 of the present embodiment.

FIG. 2 is a schematic configuration diagram of board conveyance device 20 and clamp device 30.

FIG. 3A is an explanatory diagram showing a state in which board height H1 of jig board J is detected.

FIG. 3B is an explanatory diagram showing a state in which board height H of board S is detected.

FIG. 4 is an explanatory diagram showing an electrical connection relationship of control device 70.

FIG. 5 is a flowchart showing an example of a component mounting process routine.

FIG. 6 is a flowchart showing an example of a clamp control routine.

FIG. 7A is an explanatory diagram showing an example of a state in which board S is clamped.

FIG. 7B is an explanatory diagram showing an example of the state in which board S is clamped.

FIG. 8 is a flowchart showing a modification example of the clamp control routine.

FIG. 9A is an explanatory diagram showing an example of a state in which board S is clamped.

FIG. 9B is an explanatory diagram showing an example of the state in which board S is clamped.

FIG. 9C is an explanatory diagram showing an example of the state in which board S is clamped.

### DESCRIPTION OF EMBODIMENTS

An embodiment of the present disclosure will be described using examples.

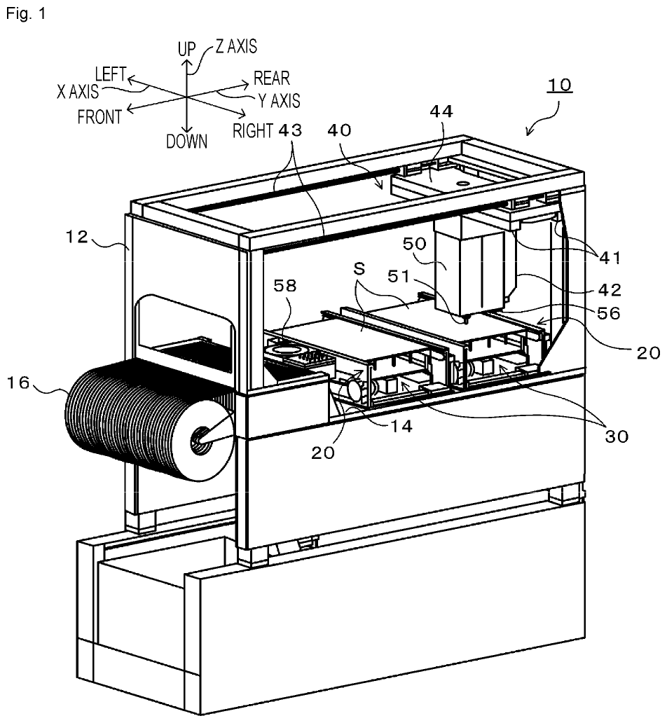

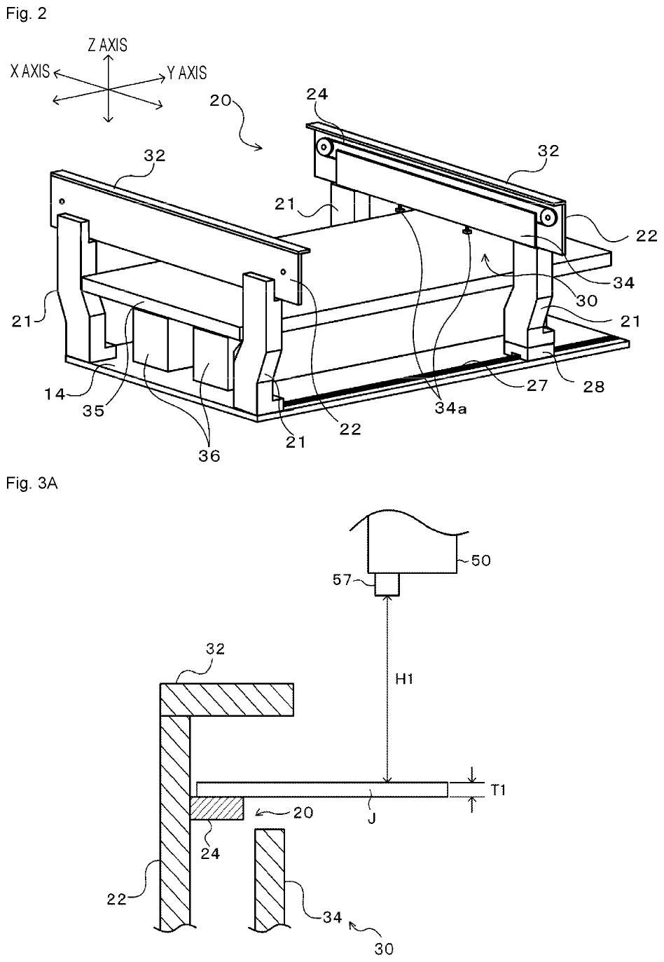

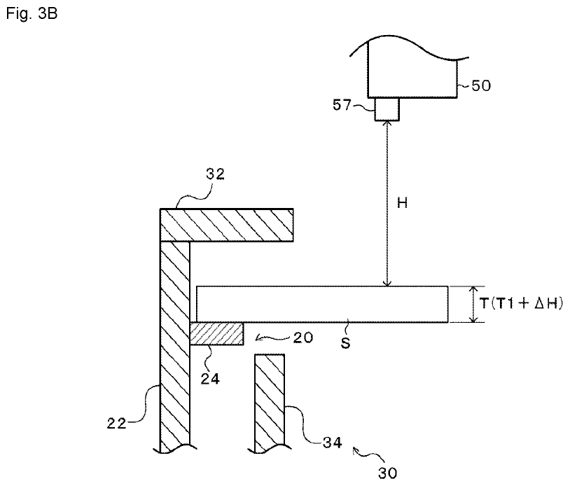

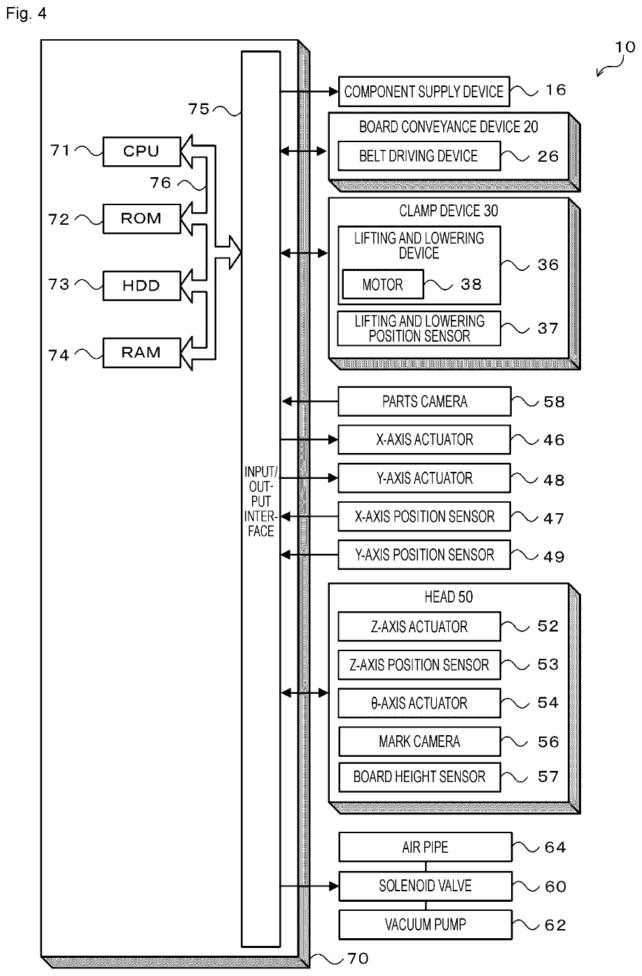

FIG. 1 is a schematic configuration diagram of component mounter 10 of the present embodiment. FIG. 2 is a schematic configuration diagram of board conveyance device 20 and clamp device 30. FIG. 3A is an explanatory diagram showing a state in which board height H1 of jig board J is detected. FIG. 3B is an explanatory diagram showing a state in which board height H of board S is detected. FIG. 4 is an explanatory diagram showing an electrical connection relationship of control device 70. It should be noted that, in FIGS. 1 and 2, a right-left direction is an X-axis direction, a front-rear (forward-backward) direction is a Y-axis direction, and an up-down direction is a Z-axis direction.

As shown in FIG. 1, component mounter 10 includes component supply device 16 for supplying component P, board conveyance device 20 for conveying board S, clamp device for clamping board S, head 50 for picking up component P to suction nozzle 51 and mounting component P on board S, XY robot 40 for moving head 50 in the XY directions, and control device (refer to FIG. 4) for controlling the entire mounter. Component supply device 16, board conveyance device 20, and clamp device 30 are mounted on support base 14 provided in a middle stage portion of housing 12. In addition, component mounter 10 includes mark camera 56 for imaging a reference mark attached to board S, board height sensor 57 for detecting a height of board S, parts camera 58 for imaging a pick-up posture of component P picked up to suction nozzle 51, and the like. Mark camera 56 or board height sensor 57 is installed in head 50 or X-axis slider 42 of XY robot 40 described later so as to be movable in the XY directions by XY robot 40.

Component supply device 16 is, for example, a tape feeder that supplies a component by pulling out a carrier tape in which components are accommodated at predetermined intervals from a reel and feeding the carrier tape to a component supply position.

As shown in FIG. 2, board conveyance device 20 is a belt conveyor device that conveys board S by conveyor belt 24. Board conveyance device 20 includes a pair of side frames 22 arranged at a predetermined interval in the Y-axis direction, conveyor belt 24 provided on each of the pair of side frames 22, and belt driving device 26 (refer to FIG. 4) for circularly driving conveyor belt 24. Each of the pair of side frames 22 is supported by two supporting columns 21 arranged in the X-axis direction. Slider 28 that is movable on guide rail 27 provided on support base 14 along the Y-axis direction is attached to each of lower end portions of two supporting columns 21 that support one of the pair of side frames 22 (side frame 22 on a right side in the FIG. 2). Board conveyance device 20 is configured to be capable of conveying boards S of different sizes by moving two supporting columns 21 to adjust the interval between the pair of side frames 22.

As shown in FIG. 2, clamp device 30 is a board holding device that holds an edge portion of board S by sandwiching with two members (board presser plate 32 and clamper 34). Clamp device 30 includes a pair of board presser plates 32 respectively provided on upper end portions of the pair of side frames 22, a pair of clampers 34, and lifting and lowering device 36 for lifting and lowering the pair of clampers 34 by driving motor 38 (refer to FIG. 4) via supporting plate 35. Supporting plate 35 is provided with multiple supporting pins for supporting a bottom surface of board S in a case where board S is clamped.

Clamper 34 is provided with protruding portion 34a protruding downward on a lower end surface, and is configured to be pressed up by bringing an upper surface of supporting plate 35 into contact with protruding portion 34a in a case where supporting plate 35 is lifted up by lifting and lowering device 36.

Board S is conveyed by circularly driving conveyor belt 24 in a state where board S is put on conveyor belt 24 (refer to FIG. 2). In addition, in a case where clamper 34 is lifted in a state where board S is put on conveyor belt 24, board S is pressed up by clamper 34 and is pressed against board presser plate 32. As a result, board S is sandwiched between clamper 34 and board presser plate 32 and is clamped.

As shown in FIG. 4, head 50 includes Z-axis actuator 52 for moving suction nozzle 51 in the up-down (Z-axis) direction, and θ-axis actuator 54 for rotating suction nozzle 51 about a Z axis. A suction port of suction nozzle 51 is configured to selectively communicate with either vacuum pump 62 or air pipe 64 via solenoid valve 60. Suction nozzle 51 is capable of applying a negative pressure to the suction port to pick up component P by driving solenoid valve such that the suction port communicates with vacuum pump 62, and is capable of applying a positive pressure to the suction port to release the picking up of component P by driving solenoid valve 60 such that the suction port communicates with air pipe 64.

Board height sensor 57 detects board height H that is a surface height of board S (a position in the Z-axis direction). Board height sensor 57 is a reflective distance sensor (such as a laser sensor or a photoelectric sensor) having a light projecting section (not shown) that project light downward and a light receiving section (not shown) that receives reflected light. Board height sensor 57 is used to control a lifting and lowering position of component P in mounting component P on board S. A board height may be a distance in the Z-axis direction between board height sensor 57 and an upper surface of board S.

Board height sensor 57 is also used to measure (calculate) thickness T of board S. Measurement of thickness T of board S using board height sensor 57 is performed as follows. That is, first, a worker prepares jig board J having a known thickness T1, and sets jig board J in board conveyance device 10 of component mounter 10. Control device 70 (refer to FIG. 4) of component mounter 10 acquires board height H1 of jig board J from board height sensor 57, for example, before manufacture is started, as shown in FIG. 3A. Then, control device 70 stores acquired board height H1 in HDD 73 in association with thickness T1 of jig board J inputted in advance. After the manufacture is started, control device 70 conveys board S with board conveyance device 20, and as shown in FIG. 3B, acquires board height H of board S from board height sensor 57, and calculates thickness T of board S using board heights H and H1 and thickness T1. Specifically, control device 70 calculates a difference MI between board height H and board height H1 (board height H1−board height H), and calculates thickness T (thickness T1+difference ΔH) of board S by a sum of known thickness T1 and difference ΔH.

As shown in FIG. 1, XY robot 40 includes a pair of Y-axis guide rails 43 provided in an upper stage portion of housing 12 along the front-rear (Y-axis) direction, Y-axis slider 44 disposed between the pair of Y-axis guide rails 43, X-axis guide rail 41 provided on a lower surface of Y-axis slider 44 along the right-left (X-axis) direction, and X-axis slider 42 movable along X-axis guide rail 41. Head 50 is attached to X-axis slider 42, and is configured to be capable of moving to any position on an XY-plane by XY robot 40. X-axis slider 42 is driven by X-axis actuator 46 (refer to FIG. 4), and Y-axis slider 44 is driven by Y-axis actuator 48 (refer to FIG. 4).

As shown in FIG. 4, control device 70 includes CPU 71, ROM 72, HDD 73, RAM 74, and input/output interface 75. These are electrically connected via bus 76. Various signals from lifting and lowering position sensor 37 for detecting a lifting and lowering position of clamper 34 (clamper position), X-axis position sensor 47 for detecting a position of X-axis slider 42, Y-axis position sensor 49 for detecting a position of Y-axis slider 44, Z-axis position sensor 53 for detecting a lifting and lowering position of suction nozzle 51 (lifting and lowering position of a component picked up by suction nozzle 51), mark camera 56, board height sensor 57, parts camera 58, or the like are input to control device 70 via input/output interface 75. Meanwhile, various control signals to component supply device 16, belt driving device 26, lifting and lowering device 36 (drive circuit for driving motor 38), X-axis actuator 46, Y-axis actuator 48, Z-axis actuator 52, θ-axis actuator 54, solenoid valve 60, or the like are output from control device 70 via input/output interface 75.

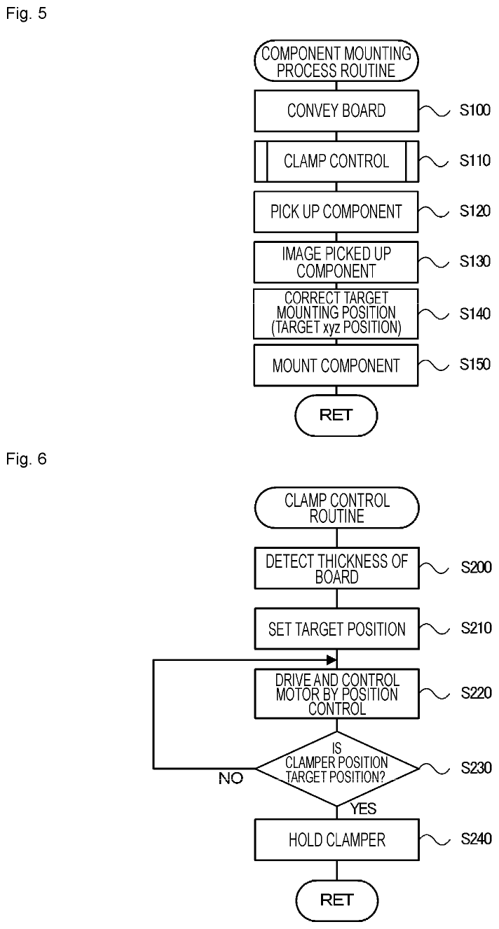

Next, operation of component mounter 10 of the present embodiment which is configured as described above will be described. FIG. 5 is a flowchart showing an example of a component mounting process routine executed by CPU 71 of control device 70. This routine is executed based on an instruction from an operator.

In a case where the component mounting process routine is executed, first, CPU 71 of control device 70 drives and controls belt driving device 26 so that board S is conveyed into a machine (S100). Then, clamp control for clamping the conveyed board S is executed (S110). The clamp control is performed by executing a clamp control routine illustrated in FIG. 6. Here, description of the component mounting process routine will be stopped, and the clamp control routine will be described.

In the clamp control routine, board height H from board height sensor 57 to board S is acquired in a case where board S is conveyed, CPU 71 measures thickness T of board S based on board height H acquired by board height sensor 57 (S200). A method for measuring thickness T of board S is as described above.

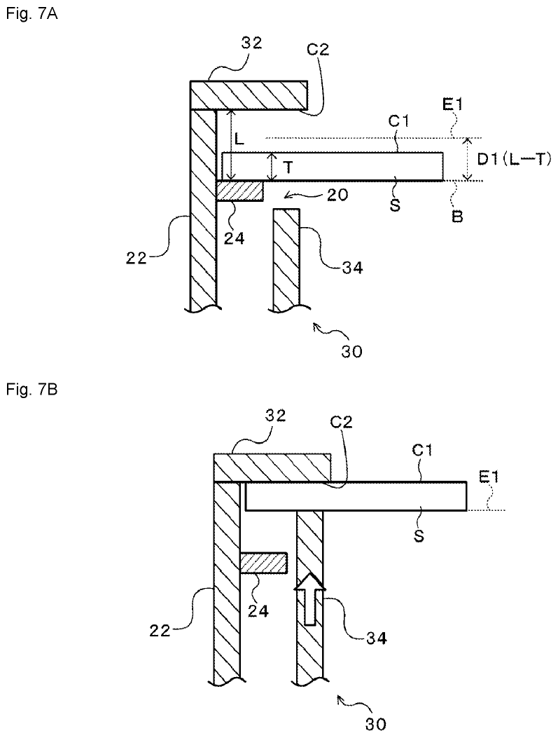

Subsequently CPU 71 sets target position E1 of clamper 34 (S210). Here, target position E1 is a position of clamper 34 for moving contacting surface C1 of board S to contacted surface C2 of board presser plate 32, and is set based on thickness T of board S. Specifically, as shown in FIG. 7A, in a case where a distance obtained by subtracting thickness T of board S from distance L from reference surface B (upper surface of conveyor belt 24) to contacted surface C2 is set to distance D1 (distance L−thickness T), target position E1 is set to a position separated upward by distance D1 from reference surface B. This is because even with the same board S, there is an individual difference in thickness T between boards S.

Subsequently, CPU 71 drives and controls motor 38 of lifting and lowering device 36 by position control such that clamper 34 is lifted at a high speed (S220). The position control is performed by driving and controlling motor 38 with feedback control (such as PI control) based on a deviation between the position of clamper 34 detected by lifting and lowering position sensor 37 and target position E1 such that both match. Subsequently, CPU 71 waits until the damper position coincides with target position E1 (S230). As shown in FIG. 7B, in a case where the position of clamper 34 coincides with target position E1, CPU 71 controls motor 38 such that clamper 34 is held (S240), and terminates the clamp control routine.

Returning to the component mounting process routine of FIG. 5, in a case where the clamp control is executed in this manner, CPU 71 performs pick-up control for picking up component P supplied from component supply device 16 to suction nozzle 51 (S120). Here, the pick-up control is specifically performed by driving and controlling XY robot 40 (X-axis actuator 46 and Y-axis actuator 48) such that suction nozzle 51 attached to head 50 moves to a side above the component supply position, then driving and controlling Z-axis actuator 52 such that suction nozzle 51 is lowered until the suction port comes into contact with component P, and driving and controlling solenoid valve 60 such that a negative pressure acts on the suction port of suction nozzle 51.

Next, CPU 71 drives and controls XY robot 40 such that component P picked up by suction nozzle 51 moves to a side above parts camera 58, and images component P with parts camera 58 (S130). Then, CPU 71 determines a suction deviation of component P with respect to suction nozzle 51 based on an image that has been captured (captured image), and a target mounting position in Z-axis direction that corrects a target mounting position of component P in a direction in which the suction deviation is resolved (S140) is set based on board height H detected by board height sensor 57. Then, after driving and controlling X-axis actuator 46, Y-axis actuator 48, Z-axis actuator 52, and solenoid valve 60 such that component P is mounted at the target mounting position (S150), the component mounting process routine is terminated. Specifically, CPU 71 drives and controls XY robot 40 (X-axis actuator 46 and Y-axis actuator 48) such that suction nozzle 51 attached to head 50 moves to a side above the target mounting position, then drives and controls Z-axis actuator 52 such that suction nozzle 51 is lowered until component P comes into contact with board S, and drives and controls solenoid valve 60 such that a positive pressure acts on the suction port of suction nozzle 51.

Here, correspondence between main elements of the present embodiment and main elements of the invention described in the section of disclosure of the invention will be described. That is, board conveyance device 20 (belt conveyor device) of the present embodiment corresponds to a conveyance device of the present disclosure, board presser plate 32 corresponds to a fixed side clamp member, clamper 34 corresponds to a movable side clamp member, motor 38 corresponds to a motor, clamp device 30 corresponds to a clamp device, board height sensor 57 corresponds to a sensor, and control device 70 corresponds to a control device. In addition, head 50 corresponds to a mounting head.

In component mounter 10 of the present embodiment described above, since it is possible to adjust contacting surface C1 of board S to contacted surface C2 of board presser plate 32 regardless of the individual difference of board S, a board is less likely to be pressed against board presser plate 32 with an excessive load. Therefore, it is possible to prevent board presser plate 32 from being deformed or to avoid bending or breakage of board S. In addition, since the clamping is performed by the position control, it is possible to shorten the time required for the clamping.

It is needless to say that the present disclosure is not limited to the embodiments described above, but may be practiced in various forms as long as they belong to scope of the present disclosure.

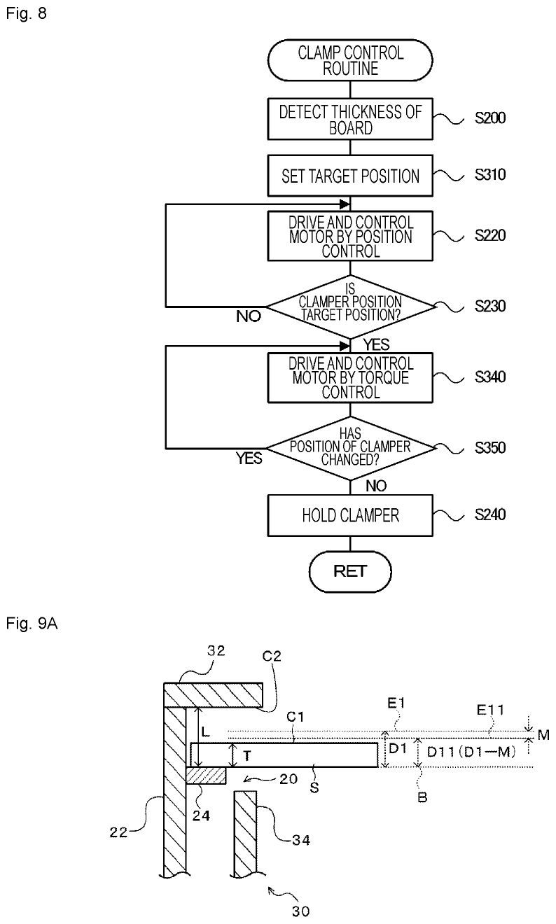

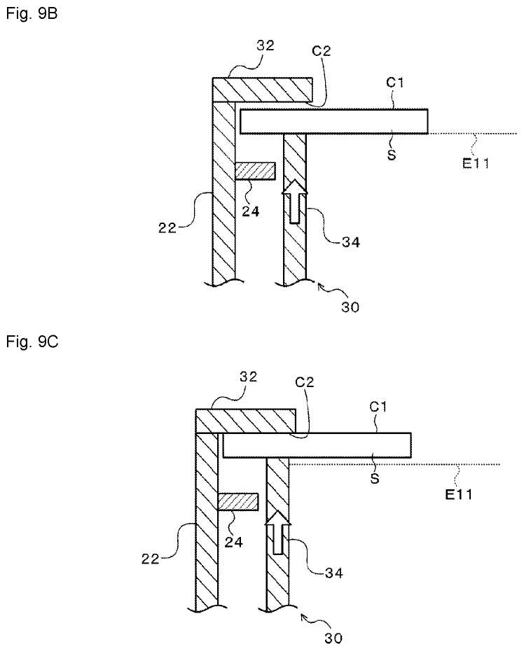

A modification example of the clamp process routine executed in component mounter 10 will be described. FIG. 8 is a flowchart showing clamp process according to the modification example. FIGS. 9A, 9B, and 9C are explanatory diagrams showing a state in which board S is clamped. Note that the same step numerals are assigned to the same processes among processes of the clamp process routine in FIG. 8 as those of the clamp process routine in FIG. 6, and the same reference signs are assigned to the same elements in FIGS. 9A, 9B, and 9C as those in FIGS. 7A and 7B, and descriptions thereof will be omitted because they will be duplicated. After S210, CPU 71 sets target position E11 (S320). Target position E11 is a position of clamper 34 for moving contacting surface C1 of board S to a position ahead of contacted surface C2 of board presser plate 32 by distance M, and is set based on thickness T of board S. Specifically, as shown in FIG. 9A, target position E11 is set to a position separated upward by distance D11 from reference surface B in a case where a distance shorter than distance D1 by distance M is set to distance D11 (distance D1−distance M). After causing the damper position to coincide with target position E11 by the position control described above as shown in FIG. 9B (S230), CPU 71 drives and controls motor 38 of lifting and lowering device 36 by torque control such that board S comes into contact with contacted surface C2 with a constant torque as shown in FIG. 9C (S340). The torque control is performed by performing feedback control based on a current from a current sensor (not shown) provided in the drive circuit so that a predetermined target current is applied to motor 38. Subsequently, CPU 71 determines whether a detected value of a clamping position of clamper 34 detected by lifting and lowering position sensor 37 has changed for a predetermined time period (S350). In a case where the detected value of the clamping position does not change for a predetermined time period, it is determined that the clamping is completed, and CPU 71 advances to step S240. On the other hand, in a case where a detection position of the clamping position has changed, CPU 71 returns to S340 again. In this case, distance M may be 0, or motor 38 may be driven and controlled by the position control to move contacting surface C1 of board S to contacted surface C2 of board presser plate 32, and then motor 38 may be driven and controlled by the torque control.

In component mounter 10 executing the clamp process routine of the modification example, at a time where contacting surface C1 of board S reaches contacted surface C2 of board presser plate 32, motor 38 is driven and controlled by the torque control, and it is possible to prevent a board from being pressed against board presser plate 32 while motor 38 is driven and controlled by the position control. Therefore, it is possible to avoid an unexpected excessive load from being applied to a board by the position control to more surely prevent deformation or the like of board presser plate 32. In addition, motor 38 is driven and controlled by the position control until the clamping position of clamper 34 coincides with target position E11. As a result, since target position E11 can be made close to a contacting position, it is possible to shorten the time required for the clamping.

In addition, although the embodiment described above has been described as component mounter 10, the embodiment may be described, for example, as a clamp control method of clamp device 30. This point is also the same in the modification example.

In the embodiment described above, side frame 22 and board presser plate 32 are formed separately from each other, but both may be formed integrally.

In the embodiment described above, a thickness of board S is measured using board height sensor 57. However, a thickness of board S may be measured using a camera. For example, CPU 71 may measure, by imaging a mark attached to board S with mark camera 56 (camera), and recognizing the mark captured in a captured image, a thickness of board S based on a size or the like of the mark.

In the above embodiment, board S is pressed up by moving clamper 34 provided below board S with lifting and lowering device 36, so that board S is brought into contact with board presser plate 32 provided above board S and is clamped. However, board S may be pressed down by arranging the damper 34 above board S, and arranging board presser plate 32 below board S, and moving clamper 34 downward with lifting and lowering device 36, so that board S is brought contact with board presser plate 32 and is clamped.

### INDUSTRIAL APPLICABILITY

The present disclosure can be applied to a manufacturing industry of a component mounter or the like.

### REFERENCE SIGNS LIST

10 component mounter, 12 housing, 14 support base, 16 component supply device, 20 board conveyance device, 21 supporting column, 22 side frame, 24 conveyor belt, 26 belt driving device, 27 guide rail, 28 slider, 30 clamp device, 32 board presser plate, 34 clamper, 34a protruding portion, 35 supporting plate, 36 lifting and lowering device, 37 lifting and lowering position sensor, 38 motor, 40 XY robot, 41 X-axis guide rail, 42 X-axis slider, 43 Y-axis guide rail, 44 Y-axis slider, 46 X-axis actuator, 47 X-axis position sensor, 48 Y-axis actuator, 49 Y-axis position sensor, 50 head, 51 suction nozzle, 52 Z-axis actuator, 53 Z-axis position sensor, 54 θ-axis actuator, 56 mark camera, 57 board height sensor, 58 parts camera, 60 solenoid valve, 62 vacuum pump, 64 air pipe, 70 control device, 71 CPU, 72 ROM, 73 HDD, 74 RAM, 75 input/output interface, 76 bus, B reference surface, C1 contacting surface, C2 contacted surface, D, D1, D11, L, M distance, H, H1 board height, ΔH difference, E1, E11 target position, J jig board, T, T1 thickness, P component, S board

1. A component mounter for mounting a component on a board, the component mounter comprising:
a conveyance device configured to convey the board;
a clamp device including a fixed side clamp member, a movable side clamp member, and a moving device configured to move up and down the movable side clamp member by driving of a motor, the clamp device being configured to sandwich and clamp the board from both sides by moving the movable side clamp member with the moving device and bringing the board conveyed by the conveyance device into contact with the fixed side clamp member;
a sensor configured to measure a thickness of the board conveyed by the conveyance device; and
a control device configured to set a target position of the movable side clamp member configured to move a contacting surface of the board to a contacted surface of the fixed side clamp member based on a detected value of the sensor, the control device being configured to drive and control the motor by position control such that a position of the movable side clamp member coincides with the target position.

2. The component mounter according to claim 1, further comprising:
a mounting head including a holding member that is capable of holding the component,
wherein the control device controls the mounting head by the position control in a state where the position of the movable side clamp member is caused to coincide with the target position such that the component held by the holding member is mounted on the board.

3. A component mounter for mounting a component on a board, the component mounter comprising:
a conveyance device configured to convey the board;
a clamp device including a fixed side clamp member, a movable side clamp member, and a moving device configured to move up and down the movable side clamp member by driving of a motor, the clamp device being configured to sandwich and clamp the board from both sides by moving the movable side clamp member with the moving device and bringing the board conveyed by the conveyance device into contact with the fixed side clamp member;
a sensor configured to measure a thickness of the board conveyed by the conveyance device; and
a control device configured to set a target position of the movable side clamp member configured to move a contacting surface of the board to a predetermined distance ahead of a contacted surface of the fixed side clamp member based on a detected value of the sensor, the control device being configured to drive and control the motor by position control such that a position of the movable side clamp member coincides with the target position, the control device being configured to drive and control, in a case where the position of the movable side clamp member reaches the target position, the motor by torque control instead of the position control such that the board comes into contact with the fixed side clamp member with a constant torque.

4. A clamp control method for use in a clamp device that includes a fixed side clamp member, a movable side clamp member, and a moving device configured to move up and down the movable side clamp member by driving of a motor, the clamp device being configured to sandwich and clamp the board from both sides by moving the movable side clamp member with the moving device and bringing the board conveyed by a conveyance device into contact with the fixed side clamp member, the method comprising:
measuring a thickness of the board; and
setting a target position of the movable side clamp member configured to move a contacting surface of the board to a contacted surface of the fixed side clamp member based on the measured thickness of the board, and driving and controlling the motor by position control such that a position of the movable side clamp member coincides with the target position.

5. A clamp control method for use in a clamp device that includes a fixed side clamp member, a movable side clamp member, and a moving device configured to move up and down the movable side clamp member by driving of a motor, the clamp device being configured to sandwich and clamp the board from both sides by moving the movable side clamp member with the moving device and bringing the board conveyed by a conveyance device into contact with the fixed side clamp member, the method comprising:
measuring a thickness of the board; and
setting a target position of the movable side clamp member configured to move a contacting surface of the board to a predetermined distance ahead of a contacted surface of the fixed side clamp member based on the measured thickness of the board, driving and controlling the motor by position control such that a position of the movable side clamp member coincides with the target position, and driving and controlling, in a case where the position of the movable side clamp member reaches the target position, the motor by torque control instead of the position control such that the board comes into contact with the fixed side clamp member with a constant torque.
